(19) United States
(12) Patent Application Publication
(10) Pub. No.: US 2012/0111408 A1
(43) Pub. Date: May 10, 2012

(54) CONTROLLED CARBON DEPOSITION

(76) Inventor: John S. Deeken, Pittsburgh, PA (US)

(21) Appl. No.: 13/283,243

(22) Filed: Oct. 27, 2011

Related U.S. Application Data
(60) Provisional application No. 61/410,726, filed on Nov. 5, 2010.

(51) Int. Cl. H01L 31/0216; H01L 31/18; H01L 31/06

(52) U.S. Cl. 136/260; 136/252; 438/95; 257/E31.015

(57) ABSTRACT

A coating of a photovoltaic device can include a self-assembled monolayer of molecules.

### CLAIM FOR PRIORITY

This application claims priority under 35 U.S.C. §119(e) to Provisional U.S. Patent Application Ser. No. 61/410,726, filed on Nov. 5, 2010, which is hereby incorporated by reference.

### TECHNICAL FIELD

This invention relates to a self-assembled monolayer of molecules.

### BACKGROUND

A photovoltaic device can include a carbon layer adjacent to a semiconductor layer and a back contact adjacent to the carbon layer. It can be difficult to control the thickness of the carbon layer. As a result, past resulting photovoltaic devices can be inefficient and can exhibit inconsistent device performance.

### DESCRIPTION OF DRAWINGS

FIG. 1 shows a self-assembled monolayer of molecules formed on a photovoltaic module surface.

FIG. 2 is a flow chart of a photovoltaic device carbon and back contact formation process.

### DETAILED DESCRIPTION

Photovoltaic devices can include multiple layers formed on a substrate (or superstrate). For example, a photovoltaic device can include a barrier layer, a transparent conductive oxide (TCO) layer, a buffer layer, a semiconductor window layer, and a semiconductor absorber layer, formed in a stack on a substrate. Each layer may in turn include more than one layer or film. For example, the semiconductor window layer and semiconductor absorber layer together can be considered a semiconductor layer. The semiconductor layer can include a first film created (for example, formed or deposited) on the TCO layer and a second film created on the first film. Additionally, each layer can cover all or a portion of the device and/or all or a portion of the layer or substrate underlying the layer. For example, a “layer” can mean any amount of any material that contacts all or a portion of a surface.

A back contact can be formed adjacent to the semiconductor absorber layer to complete the photovoltaic device. In some embodiments, a carbon-containing layer can be formed adjacent to the semiconductor absorber layer before forming the back contact. For example, for cadmium telluride thin film photovoltaic devices, a carbon-containing layer can be formed on the CdTe surface before the back contact formation.

A self assembled monolayer (SAM) is an organized layer of amphiphilic molecules in which one end of the molecule, the “head group” shows a special affinity for a substrate. A carbon-containing self-assembled monolayer can be formed adjacent to the semiconductor absorber layer before forming a back contact, as a substitute for the above-described methods of incorporating a carbon-containing layer in a photovoltaic device. Typically, head groups are connected to an alkyl chain in which the terminal end can be functionalized to vary the wetting and interfacial properties. An appropriate substrate is prepared to react with the head group. Substrates can be planar surfaces, such as silicon and metals. In some embodiments, the self-assembled monolayer molecules can include an alkyl chain as the back bone, a tail group, and a head group. The self-assembled monolayer molecules can be used on metal substrates because of the strong affinity for these metals. It can be patterned via lithography. Additionally, it can withstand harsh chemical cleaning treatments.

In one aspect, a structure can include a substrate, a transparent conductive oxide layer adjacent to the substrate, a semiconductor window layer adjacent to the transparent conductive oxide layer, a semiconductor absorber layer adjacent to the semiconductor window layer, a carbon-containing self-assembled monolayer adjacent to the semiconductor absorber layer. The structure can include a back contact adjacent to the carbon-containing self-assembled monolayer. The monolayer can include a plurality of molecule. Each molecule can include a binding end group that has an affinity for a surface of the semiconductor absorber layer and a tail end connected to the binding end group through a bond. The binding end group can be directly bound to the surface of the semiconductor absorber layer. The tail end can include carbon and can be directed from the surface of the semiconductor absorber layer.

The binding end group can include a reactive phosphorous acid. The binding end group can include a reactive phosphorous acid, such as perfluorodecylphosphonic acid (PFDP), octadecylphosphonic acid (ODP), decylphosphonic acid (DP), or octylphosphonic acid (OP). The tail end can include a carbon based group. The surface of the semiconductor absorber layer can include a metal. The binding end group can react with the surface of the semiconductor absorber layer and can form a metal phosphorous bond. The surface of the semiconductor absorber layer can be oxidized and can include a metal oxide. The binding end group can react with the oxidized surface of the semiconductor absorber layer and can form a bond. The surface of the semiconductor absorber layer can include cadmium telluride. The tail end can be connected to the binding end group through a phosphorous carbon bond. Each molecule of the one-molecule-thick layer can include an alkyl phosphonate.

In one aspect, a method of forming a photovoltaic structure can include forming a semiconductor window layer adjacent to a substrate, forming a semiconductor absorber layer adjacent to the semiconductor window layer, and forming a carbon-containing self-assembled monolayer adjacent to the semiconductor absorber layer. The step of forming a carbon-containing self-assembled monolayer can include contacting a plurality of molecules adjacent to the semiconductor absorber layer. Each molecule can include a binding end group that has an affinity for a surface of the semiconductor absorber layer and a tail end connected to the binding end group through a bond. The binding end group can be directly bound to the surface of the semiconductor absorber layer. The tail end can include carbon and can be directed from the surface of the semiconductor absorber layer.

The binding end group can include a reactive phosphorous acid. The tail end can include a carbon based group. The binding end group can form a metal phosphorous bond with the semiconductor absorber layer. The semiconductor absorber layer can be oxidized and can include a metal oxide. The binding end group can react with the oxidized semiconductor absorber layer. The semiconductor absorber layer can include cadmium telluride. The tail end can be connected to the binding end group through a phosphorous carbon bond. Each molecule of the carbon-containing self-assembled monolayer can include an alkyl phosphonate. The method can include patterning the self-assembled monolayer.

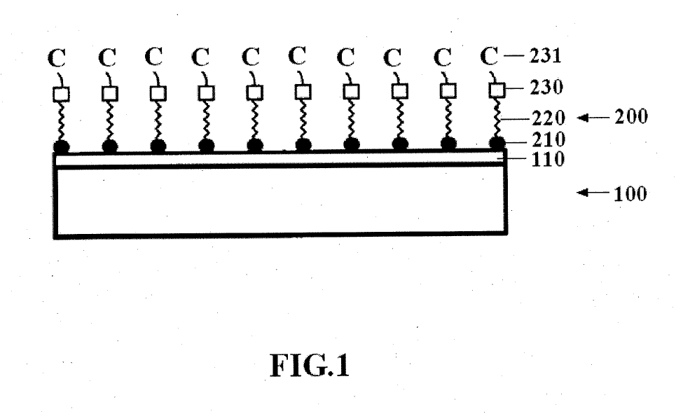

FIG. 1 depicts a photovoltaic structure including a self-assembled monolayer adjacent to the semiconductor absorber layer in the structure. A monolayer coating for a photovoltaic device can include a self-assembled monolayer 200 of molecules in contact with photovoltaic structure 100. Photovoltaic structure 100 can include any suitable combination of layers, for example a substrate on the bottom, a transparent conductive oxide layer adjacent to the substrate, and a semiconductor window layer adjacent to the transparent conductive oxide layer. These layers can include any suitable materials. Semiconductor absorber layer 110 can be formed adjacent to the semiconductor window layer in photovoltaic structure 100. Semiconductor absorber layer 110 can include cadmium telluride or any other suitable material.

Self-assembled monolayer 200 can include carbon. Self-assembled monolayer 200 can have a thickness of one molecule (for example from about 1 nm to about 10 nm, or about 1 nm to about 4 nm thick). Self-assembled monolayer 200 can thus be used in a nanoscale coating, such as a nanoscale coating adjacent to semiconductor absorber layer 110. Each molecule in self-assembled monolayer 200 can include binding end group 210 that has an affinity for semiconductor absorber layer 110. Binding end group 210 can be directly bound to semiconductor absorber layer 110. Binding end group 210 can include a reactive phosphorous acid selected from the group consisting of perfluorodecylphosphonic acid (PFDP), octadecylphosphonic acid (ODP), decylphosphonic acid (DP), and octylphosphonic acid (OP). Each molecule can include bond 220 to connect binding end group 210 and tail end group 230. Bond 220 can include a phosphonate, which can include a phosphorous acid that can combine a reactive phosphonic acid or reactive head group and a carbon-based tail group, through a phosphorous-carbon (P—C) bond. Bond 220 can include an alkyl chain. Tail end group 230 can include a carbon based group. Tail end group 230 can include carbon 231 and can be directed away from surface 110 of photovoltaic device 100.

In some embodiments, semiconductor absorber layer 110 of photovoltaic structure 100 can include a metal. Binding end group 210 reacts with semiconductor absorber layer 110 and forms a metal phosphorous bond. In some embodiments, semiconductor absorber layer 110 of photovoltaic structure 100 can be oxidized and include a metal oxide. Binding end group 210 reacts with oxidized semiconductor absorber layer 110 and forms a bond. Binding end group 210 can be covalently bound to semiconductor absorber layer 110. This bond can be a permanent chemical bond and can be stable under ambient conditions. After self-assembled monolayer 200 is formed adjacent to semiconductor absorber layer 110, a back contact layer can be formed adjacent to self-assembled monolayer 200. The back contact layer can be formed by any suitable method. The back contact layer can include any suitable material.

Self-assembled monolayer formation can occur in two steps, an initial fast step of adsorption and a second slower step of monolayer organization. Adsorption can occur at the liquid-liquid, liquid-vapor, and liquid-solid interfaces. The transport of molecules to the surface can be done by a combination of diffusion and convective transport.

In some embodiments, the nature in which the tail groups organize themselves into a straight ordered monolayer can be dependent on the inter-molecular attraction, or Van der Waals forces, between the alkyl and tail groups. To minimize the free energy of the organic layer, the molecules adopt conformations that allow high degree of Van der Waals forces with some hydrogen bonding. The small size of the self-assembled monolayer molecules can be important because Van der Waals forces arise from the dipoles of molecules and are thus much weaker than the surrounding surface forces at larger scales. The assembly process begins with a small group of molecules, usually two, getting close enough that the Van der Waals forces overcome the surrounding force. The forces between the molecules orientate themselves so they are in their straight, optimal, configuration. Then as other molecules come close by they interact with these already organized molecules in the same fashion and become a part of the conformed group. When this occurs across a large area the molecules support each other into forming their self-assembled monolayer shape seen in FIG. 1. The orientation of the molecules can be described with 2 parameters, α and β. α is the angle of tilt of the backbone from the surface normal. β is the angel of rotation along the long axis of tee molecule. In this invention, α can be any suitable value. For example, α can be in the range of 0 to 60 degrees. Likewise, β can be any suitable value. For example, β can be in the range between 30 and 40 degrees.

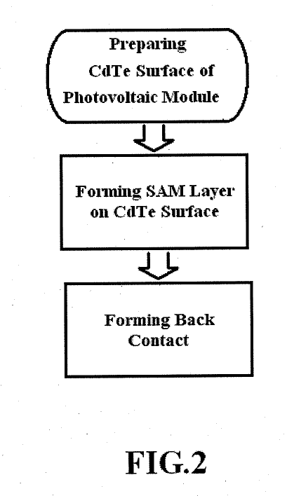

Substrates for use in self-assembled monolayers can be produced through physical vapor deposition techniques, chemical vapor deposition, electric plating or any suitable deposition technique. For carbon deposition on the interface between CdTe and back contact, as shown in FIG. 2, the first step can be preparing the CdTe surface. The preparation can include cleaning the surface. In some embodiments, the preparation can include oxidizing the surface. The following steps can include forming self-assembled monolayer layer on the CdTe surface and further forming the back contact.

A number of embodiments of the invention have been described. Nevertheless, it will be understood that various modifications may be made without departing from the spirit and scope of the invention. It should also be understood that the appended drawings are not necessarily to scale, presenting a somewhat simplified representation of various preferred features illustrative of the basic principles of the invention.

What is claimed is:

1. A structure comprising:
a substrate;
a transparent conductive oxide layer adjacent to the substrate;
a semiconductor window layer adjacent to the transparent conductive oxide layer;
a semiconductor absorber layer adjacent to the semiconductor window layer; and
a carbon-containing monolayer adjacent to the semiconductor absorber layer.

2. The structure of claim 1, further comprising a back contact adjacent to the carbon-containing self-assembled monolayer.

3. The structure of claim 1, wherein the monolayer comprises a plurality of molecules, each comprising
a binding end group that has an affinity for a surface of the semiconductor absorber layer, the binding end group directly bound to the surface of the semiconductor absorber layer; and
a tail end connected to the binding end group through a bond, the tail end comprising carbon and directed from the surface of the semiconductor absorber layer.

4. The structure of claim 3, wherein the binding end group comprises a reactive phosphorous acid.

5. The structure of claim 3, wherein the binding end group comprises a reactive phosphorous acid selected from the group consisting of perfluorodecylphosphonic acid, octadecylphosphonic acid, decylphosphonic acid, and octylphosphonic acid.

6. The structure of claim 3, wherein the tail end comprises a carbon based group.

7. The structure of claim 3, wherein the surface of the semiconductor absorber layer comprises a metal.

8. The structure of claim 7, wherein the binding end group reacts with the surface of the semiconductor absorber layer and forms a metal phosphorous bond.

9. The structure of claim 3, wherein the surface of the semiconductor absorber layer is oxidized and comprises a metal oxide.

10. The structure of claim 9, wherein the binding end group reacts with the oxidized surface of the semiconductor absorber layer and forms a bond.

11. The structure of claim 3, wherein the surface of the semiconductor absorber layer comprises cadmium telluride.

12. The structure of claim 3, wherein the tail end is connected to the binding end group through a phosphorous carbon bond.

13. The structure of claim 3, wherein each molecule of the one-molecule-thick layer comprises an alkyl phosphonate.

14. A method of forming a photovoltaic structure comprising:
forming a semiconductor window layer adjacent to a substrate;
forming a semiconductor absorber layer adjacent to the semiconductor window layer; and
forming a carbon-containing self-assembled monolayer adjacent to the semiconductor absorber layer.

15. The method of claim 14, wherein the step of forming a carbon-containing self-assembled monolayer comprises contacting a plurality of molecules adjacent to the semiconductor absorber layer, wherein each molecule comprises:
a binding end group that has an affinity for the semiconductor absorber layer, the binding end group directly bound to semiconductor absorber layer; and
a tail end connected to the binding end group through a bond, the tail end comprising carbon and directed away from the semiconductor absorber layer.

16. The method of claim 15, wherein the binding end group comprises a reactive phosphorous acid.

17. The method of claim 15, wherein the tail end comprises a carbon based group.

18. The method of claim 15, wherein the binding end group forms a metal phosphorous bond with the semiconductor absorber layer.

19. The method of claim 15, wherein the semiconductor absorber layer is oxidized and comprises a metal oxide.

20. The method of claim 19, wherein the binding end group reacts with the oxidized semiconductor absorber layer.

21. The method of claim 15, wherein the semiconductor absorber layer comprises cadmium telluride.

22. The method of claim 15, wherein the tail end is connected to the binding end group through a phosphorous carbon bond.

23. The method of claim 15, wherein each molecule of the carbon-containing self-assembled monolayer comprises an alkyl phosphonate.

24. The method of claim 15, further comprising patterning the self-assembled monolayer.
